(19) United States
(12) Patent Application Publication
(10) Pub. No.: US 2025/0334335 A1
(43) Pub. Date: Oct. 30, 2025

(54) HOLDER FOR HIGH-INTENSITY LAMPS FOR A RAPID THERMAL ANNEALING FURNACE

(71) Applicant: ANNEALSYS, MONTPELLIER (FR)

(72) Inventor: René-Pierre DUCRET, MONTPELLIER (FR)

(21) Appl. No.: 18/868,583

(22) PCT Filed: May 25, 2023
(86) PCT No.: PCT/EP2023/064106

§ 371 Date: Nov. 22, 2024

(30) Foreign Application Priority Data
Jun. 10, 2022 (FR) 22/05604

(51) Int. Cl. F27B 17/00; F27D 9/00; F27D 99/00; H05B 3/00

(52) U.S. Cl. CPC F27B 17/0025; F27D 9/00; H05B 3/0047; F27D 2009/0013; F27D 2009/0062; F27D 2099/0026; H05B 2203/032

(57) ABSTRACT

The present description concerns a holder (60) for high-intensity lamps (24) comprising a first part (62) made of a first material, intended to support the high-intensity lamps and comprising a surface (70) intended to face the high-intensity lamps, a second part (64) made of a second material different from the first material, covering the first part and attached to the first part, and a sheet (90), made of a third material different from the first material, interposed between the first part and the second part and delimiting with the second part at least one cavity (72) intended to contain a coolant.

The present patent application claims priority of French patent application FR22/05604, which is incorporated herein by reference.

### TECHNICAL FIELD

The present disclosure generally concerns high-intensity lamp holders for rapid thermal annealing furnaces and rapid thermal annealing furnaces comprising such holders.

### PRIOR ART

A rapid thermal annealing furnace is a furnace enabling to take an object, in particular a silicon substrate, to a high temperature, for example up to 1, 200° C. or more, within a very short time, generally a few seconds.

Such temperature rises are obtained by high-intensity lamps or by laser heating. In the case of high-intensity lamps, in particular of infrared lamps, the furnace comprises a lamp holder. The holder comprises a wall, facing the lamps, adapted to reflecting the radiation emitted by the lamps towards the object to be heated. It is further generally necessary to provide a system for cooling the holder, for example a system for circulating water through inner pipes of the holder.

It is known to form a high-intensity lamp holder for a rapid thermal annealing furnace with aluminum parts assembled by screwing and cooled with water. A disadvantage is that the water circulation may cause corrosion of the aluminum, and require maintenance operations to replace parts of the holder.

### SUMMARY OF THE INVENTION

An object of an embodiment is to provide a high-intensity lamp holder for a rapid thermal annealing furnace overcoming all or part of the disadvantages of existing high-intensity lamp holders.

Another object of an embodiment is for the method of manufacturing the high-intensity lamp holder to be simple.

Another object of an embodiment is for the manufacturing cost of the high-intensity lamp holder to be decreased.

Another object of an embodiment is for the maintenance cost of the high-intensity lamp holder to be decreased.

Another object of an embodiment is for the holder to comprises a wall adapted to reflecting the radiation emitted by the lamps.

Another object of an embodiment is for the holder to incorporate pipes for the circulation of a coolant.

An embodiment provides a holder for high-intensity lamps comprising:
a first part made of a first material, intended to support the high-intensity lamps and comprising a surface intended to face the high-intensity lamps;
a second part made of a second material, different from the first material, covering the first part and attached to the first part; and
a sheet, made of a third material different from the first material, interposed between the first part and the second part and delimiting with the second part at least one cavity designed to contain a coolant.

According to an embodiment, the second and third materials are stainless.

According to an embodiment, the second and third materials are poorer heat conductors than the first material.

According to an embodiment, the first material is comprised in the group comprising aluminum, aluminum alloys having good aptitude for mechanical mirror polishing, copper, and copper alloys such as brass.

According to an embodiment, the second material is comprised in the group comprising stainless steel, plastics resistant to temperatures higher than 100° C., and composite materials resistant to temperatures higher than 100° C.

According to an embodiment, the third material is comprised in the group comprising stainless steel, copper, and copper alloys such as brass.

According to an embodiment, the thickness of the sheet is in the range from 0.03 mm to 0.3 mm.

An embodiment also provides a rapid thermal annealing furnace comprising high-intensity lamps and a holder for said high-intensity lamps such as defined hereabove.

According to an embodiment, the high-intensity lamps are infrared lamps.

According to an embodiment, the furnace comprises a system for circulating the coolant in the cavity.

According to an embodiment, the coolant comprises water.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a partial and very simplified cross-section view of an example of a rapid thermal annealing furnace;

FIG. 2 is a partial and simplified cross-section view of an example of a high-intensity lamp holder for a rapid thermal annealing furnace;

FIG. 3 is a partial and simplified cross-section view of a high-intensity lamp holder for a rapid thermal annealing furnace; and

FIG. 4 is an exploded view of the embodiment of the holder of FIG. 3.

### DESCRIPTION OF EMBODIMENTS

Like features have been designated by like references in the various figures. In particular, the structural and/or functional features that are common among the various embodiments may have the same references and may dispose identical structural, dimensional and material properties. For clarity, only those steps and elements which are useful to the understanding of the described embodiments have been shown and are described in detail.

Unless specified otherwise, the expressions “about”, “approximately”, “substantially”, and “in the order of” signify plus or minus 10%, preferably of plus or minus 5%. Unless specified otherwise, ordinal numeral adjectives, such as “first”, “second”, etc., are used only to distinguish elements from one another. In particular, these adjectives do not limit the described embodiments to a specific order of these elements.

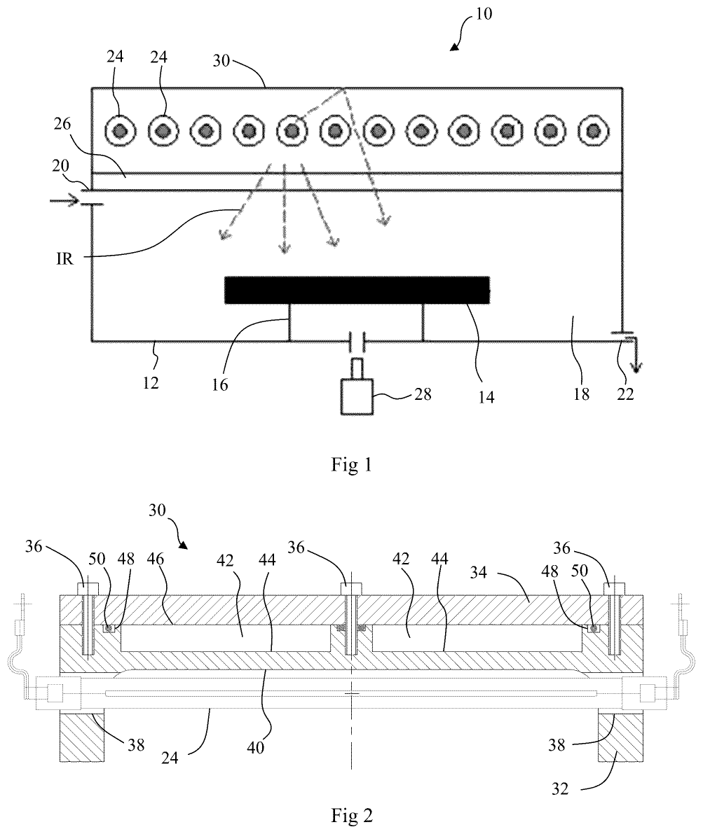

FIG. 1 is a partial and simplified cross-section view of an example of a rapid thermal annealing furnace 10.

Furnace 10 comprises an enclosure 12, also called reactor, having the object 14 to be treated, which is arranged on a support base 16, placed therein. The object 14 to be treated is, for example, a silicon substrate. An inert gas may be injected into the inner volume 18 of reactor 12 by an injection system 20. The inner volume 18 of reactor 12 may be maintained at low pressure by a pumping system 22. The object 14 to be treated is heated by the radiation emitted by high-intensity lamps 24 held by a holder 30. High-intensity lamps 24 are, for example, infrared lamps.

A quartz porthole 26 ensures the tightness of the inner volume 18 of reactor 12, while giving way to the IR radiation emitted by lamps 24. Holder 30 is further adapted to reflecting back towards porthole 26 the IR radiation emitted by lamps 24. The walls of reactor 12 are in particular cooled to avoid contaminating substrate 14 and to protect the control and/or measurement equipment fitting reactor 12. The temperature of substrate 14 may be controlled by a regulator coupled to a pyrometer 28.

FIG. 2 is a partial and simplified cross-section view of an example of the holder 30 of lamps 24, a single lamp 24 being shown in FIG. 2. The cross-section plane of FIG. 2 is orthogonal to the cross-section plane of FIG. 1. Holder 30 is formed of a first part 32 and of a second part 34, attached to each other by means of screws 36. Preferably, there are no seals between the first part 32 and the second part 34.

Lamps 24 are attached to the first part 32. The first part 32 for example comprises, for each lamp 24, two openings 38 having the ends of lamp 24 housed therein. The first part 32 comprises a wall 40 facing lamps 24 and which forms a mirror reflecting the radiation emitted by lamps 24.

When parts 32 and 34 are assembled, they delimit inner cavities 42 in which a coolant, for example, water, is circulated. Inner cavities 42 may be delimited by recesses 44 provided in the first part 32, which are closed by a planar surface 46 of the second part 34, when the second part 34 is assembled to the first part 32.

The first part 32 may comprise grooves 48 on the side of the second part 34. The tightness of inner cavities 42 may be obtained by O-rings 50 arranged in grooves 48.

When lamps 24 are infrared lamps, parts 32 and 34 may be made of aluminum, which is a low-cost material, a good heat conductor, and a good reflector of the infrared radiation emitted by lamps 24.

A disadvantage is that parts 32 and 34 may corrode in contact with the coolant circulating in cavities 42 when the latter comprises water. A possibility would be to provide an anticorrosion treatment on the walls of cavities 42. However, this tends to make the method of manufacturing holder 30 complex and increases its manufacturing cost.

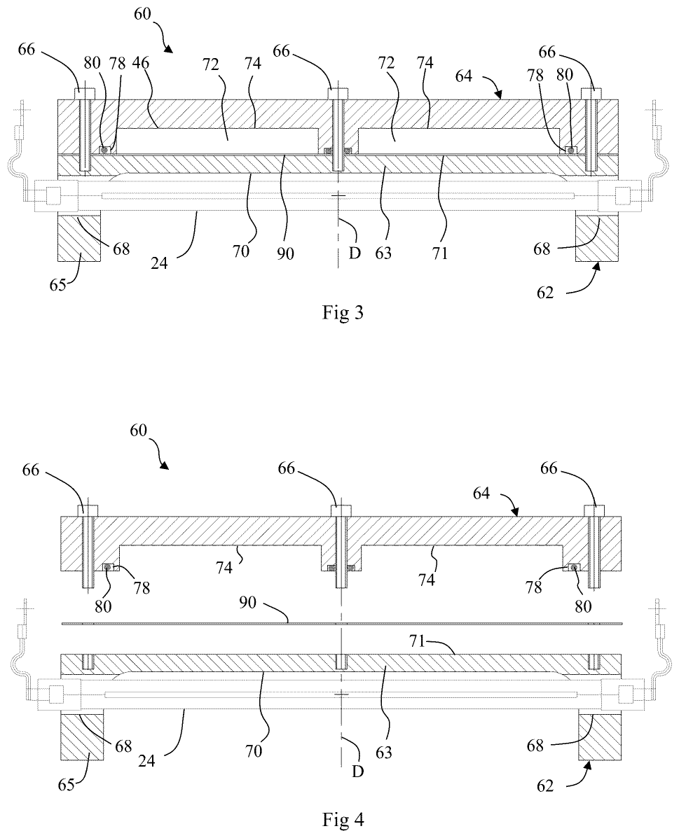

FIG. 3 is a partial and simplified cross-section view of a holder 60 of lamps 24 capable of being used as a holder 30 for the furnace 1 shown in FIG. 1. FIG. 4 is an exploded view with a cross-section of the holder 60 of FIG. 3. The cross-section plane of FIGS. 3 and 4 is orthogonal to the cross-section plane of FIG. 1. A single lamp 24 is shown in FIGS. 3 and 4.

Holder 60 comprises a stack of a first part 62, of a sheet 90, and of a second part 64, attached to one another by means of screws 66, three screws being shown as an example in FIGS. 3 and 4. Sheet 90 is sandwiched between the first part 62 and the second part 64. Preferably, there are no seals between the first part 62, the second part 64, and sheet 90.

The first part 62 comprises a portion 63, of generally square or rectangular cross-section, of central axis D, continued by a peripheral rim 65 which extends on the side opposite to the second part 64. Lamps 24 are attached to the rim 65 of the first part 62. The rim 65 of the first part 62 comprises, for example, for each lamp 24, two openings 68 having the ends of lamp 24 housed therein. The first part 62 comprises a wall 70 facing lamps 24 and forming a mirror reflecting the radiation emitted by lamps 24. According to an embodiment, wall 70 comprises a flat, square, or rectangular area at the central portion 63 of the first part 62, and comprises square or rectangular areas at rim 65. The first part 62 comprises a surface 71 located on the side of sheet 90 and against which sheet 90 is applied when the first part 62, sheet 90, and the second part 64 are attached to one another by means of screws 66. According to an embodiment, surface 71 is planar and sheet 90 is planar. According to an embodiment, surface 71 is of square or rectangular shape.

When they are assembled, parts 62, 64 and sheet 90 delimit inner cavities 72 in which a coolant, for example water possibly containing additives, is circulated in operation. Inner cavities 72 are delimited by recesses 74 provided in the second part 64, which are closed by sheet 90 when the second part 64 is assembled to the first part 62 with the interposition of sheet 90. The second part 64 comprises grooves 78 on the side of the first part 62. The tightness of inner cavities 72 may be obtained by O-rings 80 arranged in grooves 78.

The first part 62 is made of a first material. According to an embodiment, the first material is comprised in the group comprising aluminum, aluminum alloys having a good aptitude for mechanical mirror polishing, copper, and copper alloys such as brass. Surface 70 forming a mirror to the radiation of lamps 24 may be simply obtained by mechanical polishing without it being necessary to provide the deposition of a reflective coating on surface 70. According to an embodiment, the roughness Ra of surface 70 is lower than 0.2. According to an embodiment, surface 70 reflects more than 90% of the radiation emitted by lamps 24. According to an embodiment, the radiation emitted by lamps 24 has a wavelength in the range from 0.5 μm to 4 μm, preferably with an emission peak at 1 μm for a 2,500-K filament temperature.

The average thickness of the first part 62 in the portions facing cavities 72 is in the range from 4 mm to 8 mm. According to an embodiment, the thickness of the peripheral rim 65 of the first part 62, measured along axis D, is in the range from 10 mm to 20 mm. Since the first material is a good heat conductor, it allows an efficient dissipation towards the coolant of the heat transmitted to the first part 62 by lamps 24, without it being necessary to provide cavities for the circulation of the coolant directly in the rim 65 of the first part 62.

The second part 64 is made of a second material different from the first material. The second material is stainless. The second material may be a poorer heat conductor than the first material. According to an embodiment, the second material is comprised in the group comprising stainless steel, plastics resistant to temperatures higher than 100° C., in particular polyoxymethylene-based thermoplastics, and composite materials resistant to temperatures higher than 100° C. The depth of each recess 74, measured along axis D, may be in the range from 5 mm to 10 mm.

Sheet 90 is made of a third material different from the first material and possibly identical to the second material. The third material is stainless. The third material may be less thermally conductive than the first material, but is preferably metallic to ensure a sufficient heat conduction. According to an embodiment, the third material is comprised in the group comprising stainless steel, copper, and copper alloys such as brass. According to an embodiment, the thickness of sheet 90 is smaller than 0.5 mm, preferably in the range from 0.03 mm to 0.3 mm. The small thickness of sheet 90 makes it easy to deform.

According to an embodiment, sheet 90 fully covers surface 71 of the first part 62. In the case where surface 71 corresponds to a square or to a rectangle, sheet 90 corresponds to a square or to a rectangle of same surface area.

In operation, the coolant is in contact only with stainless materials. This advantageously enables to prevent the corrosion of holder 60, particularly when the coolant is based on water. Further, it is not necessary to provide an anticorrosion treatment on the wall of cavity 72. The method of manufacturing holder 60 thus remains simple.

In operation, the coolant present in cavities 72 is under pressure and holds sheet 90 against the first part 62. A direct contact is thus obtained between sheet 90 and the first part 62 substantially with no interposition of an air film. A good heat transmission between the first part 62 and sheet 90 is thus obtained. According to an embodiment, the pressure of the coolant in cavities 72 is in the range from 0.1 MPa to 0.5 MPa, preferably from 0.3 MPa to 0.4 MPa. Further, given the small thickness of sheet 90, even if sheet 90 is made of a third material which is a poorer heat conductor than the first material forming the first part 62, the third material however being preferably metallic, the heat conduction between the first part 62 and the cooling liquid through the sheet 90 of very low thickness is sufficiently efficient to allow a suitable cooling of the first part 62 in operation.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. Holder for high-intensity lamps comprising:
a first part made of a first material, intended to support the high-intensity lamps and comprising a surface intended to face the high-intensity lamps;
a second part made of a second material, different from the first material, covering the first part and attached to the first part; and
a sheet, made of a third material different from the first material, interposed between the first part and the second part and delimiting with the second part at least one cavity intended to contain a coolant.

2. Holder according to claim 1, wherein the second and third materials are stainless.

3. Holder according to claim 1, wherein the second and third materials are poorer heat conductors than the first material.

4. Holder according to claim 1, wherein the first material is comprised in the group comprising aluminum, aluminum alloys having a good aptitude for mechanical mirror polishing, copper, and copper alloys such as brass.

5. Holder according to claim 1, wherein the second material is comprised in the group comprising stainless steel, plastics resistant to temperatures higher than 100° C., and composite materials resistant to temperatures higher than 100° C.

6. Holder according to claim 1, wherein the third material is comprised in the group comprising stainless steel, copper, and copper alloys such as brass.

7. Holder according to claim 1, wherein the thickness of the sheet is in the range from 0.03 mm to 0.3 mm.

8. Rapid thermal annealing furnace comprising high-intensity lamps and a holder for said high-intensity lamps according to claim 1. 7.

9. Rapid thermal annealing furnace according to claim 8, wherein the high-intensity lamps are infrared lamps.

10. Rapid thermal annealing furnace according to claim 8, comprising a system for circulating the coolant in the cavity.

11. Rapid thermal annealing furnace according to claim 8, wherein the coolant comprises water.
